(19) United States
(12) Patent Application Publication
(10) Pub. No.: US 2010/0087062 A1
(43) Pub. Date: Apr. 8, 2010

(54) HIGH TEMPERATURE BD DEVELOPMENT FOR MEMORY APPLICATIONS

(75) Inventors: Annamalai Lakshmanan, Fremont, CA (US); Dante Manalo, Santa Clara, CA (US); Nagarajan Rajagopalan, Santa Clara, CA (US); Francimar C. Schmitt, Santa Clara, CA (US); Bok Hoen Kim, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/246,374

(22) Filed: Oct. 6, 2008

(51) Int. Cl. H01L 21/4763; H01L 21/31

(52) U.S. Cl. 438/675; 438/763; 257/E21.249; 257/E21.495

(57) ABSTRACT

A method and apparatus for depositing organosilicate dielectric layers having good adhesion properties and low dielectric constant. Embodiments are described in which layers are deposited at low temperature and at high temperature. The low temperature layers are generally post-treated, whereas the high temperature layers need no post treating. Adhesion of the layers is promoted by use of an initiation layer.

### BACKGROUND OF THE INVENTION

1. Field of the Invention

Embodiments of the present invention generally relate to the fabrication of integrated circuits. More particularly, embodiments of the present invention relate to a process for depositing low dielectric constant layers on a substrate.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. The continued reduction in device geometries has generated a demand for inter layer dielectric films having lower dielectric constant (k) values because the capacitive coupling between adjacent metal lines must be reduced to further reduce the size of devices on integrated circuits.

Much research has been devoted to improving the performance of dielectric layers in logic devices. Extreme low-k films having dielectric constants less than 2.5 have been developed featuring a nano-porous structure that helps lower the dielectric constant of the film. As similar scaling demands impact processes for fabricating memory devices, attempts have been made to apply these same films to a memory structure. Processes for fabricating memory devices, however, feature subsequent high-temperature steps that cause the dielectric film to out-gas volatile species and shrink. Thus, there is a need for a low-k dielectric that is stable at high temperatures prevalent in memory device fabrication processes.

### SUMMARY OF THE INVENTION

Embodiments of the invention provide a method of forming a memory device, comprising depositing a dense low-k dielectric film comprising silicon, oxygen, and carbon, and having one or more terminal methyl groups, while depositing the dense low-k dielectric film, removing volatile carbon-containing species from the film, forming openings in the dense low-k dielectric film, and filling the openings in the dense low-k dielectric film with a conductive material, wherein depositing the dense low-k dielectric film comprises reacting a gas mixture comprising a silicon precursor, a carbon precursor, and an oxygen precursor in the presence of RF power at a temperature at or above about 450° C., and removing volatile carbon-containing species from the film comprises maintaining the substrate at a temperature at or above about 450° C.

Other embodiments of the invention provide a method of forming a memory device on a substrate, comprising reacting a gas mixture comprising a silicon precursor, a carbon precursor, and an oxygen precursor at a temperature at or above about 450° C. in the presence of RF power, depositing a low-k film having terminal methyl groups incorporated therein, forming openings in the low-k film, and filling the openings with a conductive material.

Other embodiments of the invention provide a method of forming a device on a substrate, comprising disposing the substrate in a process chamber, providing a first gas mixture comprising an alkyl-substituted cyclotetrasiloxane compound, an oxidizing compound, and a carrier gas, to a reaction zone in the process chamber, maintaining a temperature of the gas mixture in the reaction zone at a temperature at or above 450° C., applying dual-frequency RF power to the reaction zone, reacting the first gas mixture to form a dense initiation layer on the substrate, increasing the quantity of the alkyl-substituted cyclotetrasiloxane compound to form a second gas mixture, reacting the second gas mixture to form a dense bulk deposition layer on the substrate, stopping the alkyl-substituted cyclotetrasiloxane compound to form a third gas mixture, and reacting the third gas mixture to form a hermetic oxide cap on the substrate.

Other embodiments of the invention provide a method for depositing an organosilicate dielectric layer comprising sequentially depositing a silicon oxide layer having low carbon content and a carbon doped silicon oxide layer having a low dielectric constant within the same processing chamber without plasma arcing. In one embodiment, the method for depositing an organosilicate dielectric layer includes flowing an interface gas mixture comprising one or more organosilicon compounds and one or more oxidizing gases through a gas distribution plate, such as a showerhead, to a substrate surface at first deposition conditions, wherein a high frequency RF (HFRF) bias is applied to a powered electrode, such as the showerhead, to deposit a silicon oxide interface layer having less than about 3 atomic percent carbon, then increasing the flow rate of the one or more organosilicon compounds while depositing a transition layer on the interface layer, and then flowing a final gas mixture to deposit a carbon doped silicon oxide layer having at least 10 atomic percent carbon. Changing process conditions as described herein substantially reduces variation of DC bias of the powered electrode to a variation less than 60 volts during processing.

Other embodiments of the invention provide methods for depositing an organosilicate dielectric layer including concurrently increasing a low frequency RF (LFRF) power while increasing the flow rate of the one or more organosilicon compounds (e.g., OMCTS, TMCTS) to deposit the transition layer therebetween. In one aspect, the LFRF power is increased at a ramp-up rate between about 15 W/sec. and 45 W/sec. In another aspect, the organosilicon compound is octamethylcyclotetrasiloxane (OMCTS) and the increasing flow of the OMCTS is at a ramp-up rate in a range of about 300 mg/min./sec. to about 5,000 mg/min./sec.

Other embodiments of the invention provide methods for depositing an organosilicate dielectric layer including sequentially flowing an interface gas mixture comprising a flow rate of octamethylcyclotetrasiloxane (OMCTS) and a flow rate of oxygen gas at a OMCTS:O₂ molar flow rate ratio of less than about 0.1 through a gas distribution plate to a substrate surface at first deposition conditions comprising a HFRF bias applied to the gas distribution plate to deposit a silicon oxide interface layer having less than about 1 atomic percent carbon, and then increasing the flow rate of the OMCTS at a ramp-up rate in a range of about 300 mg/min./sec. to about 5,000 mg/min./sec. while concurrently increasing a LFRF power applied to the gas distribution plate at a ramp-up rate between about 15 W/sec. and 45 W/sec. to deposit a transition layer on the interface layer, wherein DC bias of the gas distribution plate varies less than 60 volts, and subsequently flowing a final gas mixture to deposit a carbon doped silicon oxide layer having at least 10 atomic percent carbon.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram illustrating a first method according to an embodiment of the invention.

FIG. 2 is a cross-sectional view of an organosilicate dielectric layer formed according to embodiments of the invention.

FIG. 3 is a cross-sectional diagram of an exemplary processing chamber that may be used for practicing embodiments of the invention.

FIG. 4 is a process flow diagram illustrating a second method according to another embodiment of the invention.

FIG. 5 is a process flow diagram illustrating a third method according to a further embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention provide a method of depositing an organosilicate dielectric layer exhibiting high adhesion strength to an underlying substrate, carbon containing silicon oxide layer, or silicon carbon layer without plasma arcing. Generally, one or more process conditions are varied during the deposition of the organosilicate dielectric layer such that plasma-induced damage (PID) to the substrate is minimized.

Embodiments of the invention also generally provide methods and apparatus for forming low dielectric constant insulating layers for semiconductor devices. The low-k layers of certain embodiments of the present invention are generally suited to processes that require high temperature processing steps subsequent to formation of the layers. For example, manufacture of memory devices generally requires thermal stability up to at least 600° C. due to severity of subsequent processing steps. As mentioned above, conventionally formed low-k layers have failed to meet this need due to thermal instability at these extreme temperatures.

In one embodiment, a method of depositing an organosilicate dielectric layer exhibiting high adhesion strength includes varying the composition of the process gas in the process chamber as the organosilicate dielectric layer is deposited onto a substrate disposed therein such that PID to the substrate is minimized. Varying the composition of the process gas during deposition provides an organosilicate dielectric layer having an initial layer, i.e., interface layer or initiation layer, compositionally modified to provide good adherence to the underlying substrate.

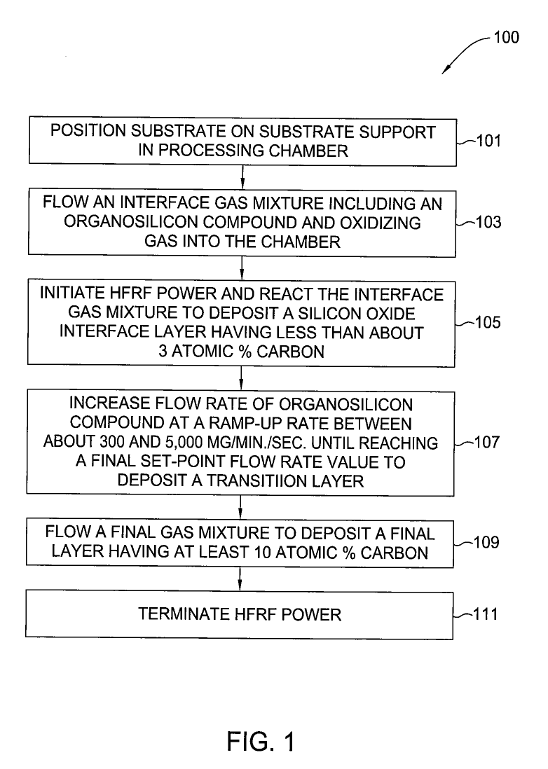

FIG. 1 is a process flow diagram illustrating a method of depositing an organosilicate dielectric layer, according to a first embodiment of the invention. At 101, a substrate is positioned on a substrate support in a processing chamber capable of performing PECVD. At 103, an interface gas mixture having a composition including one or more organosilicon compounds and one or more oxidizing gases is introduced into the chamber through a gas distribution plate, such as a showerhead. At 105, a high frequency radio-frequency (HFRF) power is applied to an electrode, such as the showerhead, in order to provide plasma processing conditions in the chamber. The interface gas mixture is reacted in the chamber in the presence of HFRF power to deposit an interface layer comprising a silicon oxide layer having less than 3 atomic percent carbon (excluding hydrogen), and preferably less than 1 atomic percent carbon, that adheres strongly to the underlying substrate. At 107, the flow rate of the one or more organosilicon compounds is increased at a ramp-up rate between about 300 mg/min./sec. and about 5,000 mg/min./sec., in the presence of the HFRF power, to deposit a transition layer until reaching a predetermined final gas mixture. The ramp-up of the flow rate conditions is performed such that variation in DC bias of the gas distribution plate is less than 60 volts, preferably less than 30 volts, to avoid PID. Upon reaching the predetermined final gas mixture, the final gas mixture having a composition including the one or more organosilicon compounds is reacted in the chamber, in the presence of HFRF power, to deposit a final layer comprising a carbon doped silicon oxide layer having at least 10 atomic percent carbon. The HFRF power is terminated at 111. The chamber pressure is maintained during the HFRF power termination, such as by not opening the chamber throttle valve.

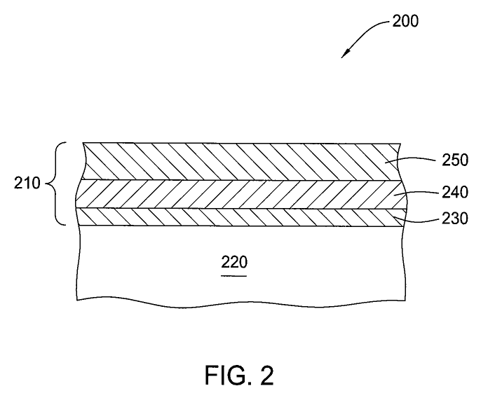

FIG. 2 schematically illustrates a cross-sectional view of an organosilicate dielectric layer formed according to embodiments of the present invention. An organosilicate dielectric layer 210 is deposited on an underlying layer (e.g., barrier layer) 220 of the surface of a substrate disposed in a processing chamber capable of performing PECVD. A plasma of the interface gas mixture comprising a flow rate of one or more organosilicon compounds is formed, as described above with respect to items 103 and 105 of FIG. 1, to deposit a silicon oxide interface layer 230 having less than 3 atomic percent carbon, preferably less than 1 atomic percent carbon, and strong adhesion to the underlying layer 220. The interface layer 230 is deposited to a thickness in a range of about 5 Å to about 100 Å, preferably about 20 Å to about 60 Å. After depositing the interface layer 230, the flow rate of the one or more organosilicon compounds is gradually increased to a predetermined final gas mixture, such that variation in DC bias of the gas distribution plate is less than 60 volts to avoid PID. While gradually increasing the flow rate of the one or more organosilicon compounds, a transition layer 240 is deposited onto the interface layer 230, as described above with respect to item 107 of FIG. 1. As deposition proceeds, the carbon concentration increases while the composition of the gas mixture is varied during deposition of the transition layer until reaching the final gas mixture. The transition layer 240 is deposited to a thickness in a range of about 10 Å to about 300 Å, preferably about 100 Å to about 200 Å. Upon reaching the final gas mixture composition, plasma of the final gas mixture comprising a flow rate of one or more organosilicon compounds at the final set-point flow rate value is formed, as described above with respect to item 109 of FIG. 1, to deposit a carbon doped silicon oxide layer 250 having at least about 10 atomic percent carbon to a desired thickness. Preferably, the carbon doped silicon oxide layer 250 comprises a carbon concentration in a range of about 10 atomic percent carbon to 40 atomic percent carbon, and more preferably in a range of about 20 atomic percent carbon to 30 atomic percent carbon. The carbon doped silicon oxide layer 250 is deposited to a thickness in a range of about 200 Å to about 10,000 Å until the HFRF power is terminated at 111. The carbon content of the deposited layers refers to an elemental analysis of the film structure. The carbon content is represented by the percent of carbon atoms in the deposited film, excluding hydrogen atoms, which are difficult to quantify. For example, a film having an average of one silicon atom, one oxygen atom, one carbon atom and two hydrogen atoms has a carbon content of 20 atomic percent (one carbon atom per five total atoms), or a carbon content of 33 atomic percent excluding hydrogen atoms (one carbon atom per three total atoms).

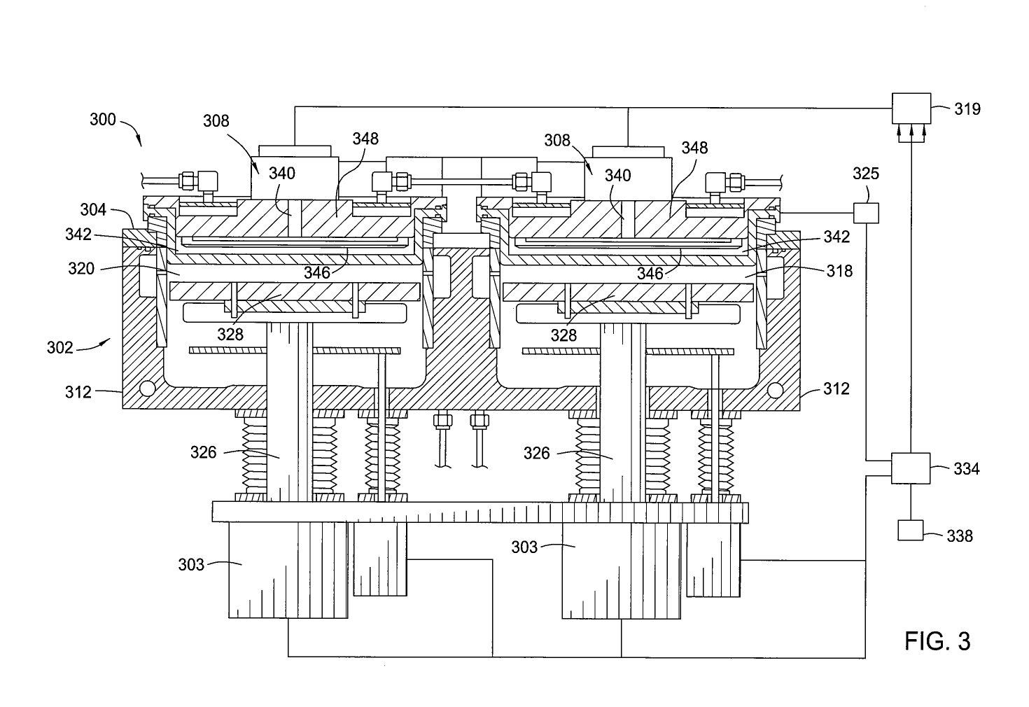

FIG. 3 presents a cross-sectional, schematic diagram of a chemical vapor deposition (CVD) chamber 300 for depositing a carbon-doped silicon oxide layer. This figure is based upon features of the PRODUCER® chambers currently manufactured by Applied Materials, Inc. The PRODUCER CVD chamber (200 mm or 300 mm) has two isolated processing regions that may be used to deposit carbon-doped silicon oxides and other materials.

The chamber 300 has a body 302 that defines separate processing regions 318 and 320. Each of the processing regions 318 and 320 has a pedestal 328 for supporting a substrate (not seen) within the chamber 300. The pedestal 328 typically includes a heating element (not shown). Preferably, the pedestal 328 is movably disposed in each of the processing regions 318 and 320 by a stem 326 which extends through the bottom of the chamber body 302 where it is connected to a drive system 303. Internally movable lift pins (not shown) are preferably provided in the pedestal 328 to engage a lower surface of the substrate. The lift pins are engaged by a lift mechanism (not shown) to receive a substrate before processing, or to lift the substrate after deposition for transfer to the next station.

Each of the processing regions 318 and 320 also preferably includes a gas distribution assembly 308 disposed through a chamber lid 304 to deliver gases into the processing regions 318 and 320. The gas distribution assembly 308 of each processing region normally includes a gas inlet passage 340 through manifold 348 which delivers gas from a gas distribution manifold 319 through a blocker plate 346 and then through a showerhead 342. The showerhead 342 includes a plurality of nozzles (not shown) through which gaseous mixtures are injected during processing. An RF (radio frequency) source 325 provides a bias potential to the showerhead 342 to facilitate generation of a plasma between the showerhead and the pedestal 328. During a plasma-enhanced chemical vapor deposition process, the pedestal 328 may serve as a cathode for generating the RF bias within the chamber body 302. The cathode is electrically coupled to an electrode power supply to generate a capacitive electric field in the deposition chamber 300. Typically an RF voltage is applied to the cathode while the chamber body 302 is electrically grounded. Power applied to the pedestal 328 creates a substrate bias in the form of a negative voltage on the upper surface of the substrate. This negative voltage is used to attract ions from the plasma formed in the chamber 300 to the upper surface of the substrate. The capacitive electric field forms a bias which accelerates inductively formed plasma species toward the substrate to provide a more vertically oriented anisotropic filming of the substrate during deposition, and etching of the substrate during cleaning.

During processing, process gases are uniformly distributed radially across the substrate surface. The plasma is formed from one or more process gases or a gas mixture by applying RF energy from the RF source 325 to the showerhead 342, which acts as a powered electrode. Film deposition takes place when the substrate is exposed to the plasma and the reactive gases provided therein. The chamber walls 312 are typically grounded. The RF source 325 can supply either a single or mixed frequency RF signal to the showerhead 346 to enhance the decomposition of any gases introduced into the processing regions 318 and 320.

A system controller 334 controls the functions of various components such as the RF source 325, the drive system 303, the lift mechanism, the gas distribution manifold 319, and other associated chamber and/or processing functions. The system controller 334 executes system control software stored in a memory 338, which in the preferred embodiment is a hard disk drive, and can include analog and digital input/output boards, interface boards, and stepper motor controller boards. Optical and/or magnetic sensors are generally used to move and determine the position of movable mechanical assemblies.

The above CVD system description is mainly for illustrative purposes, and other plasma processing chambers may also be employed for practicing embodiments of the invention.

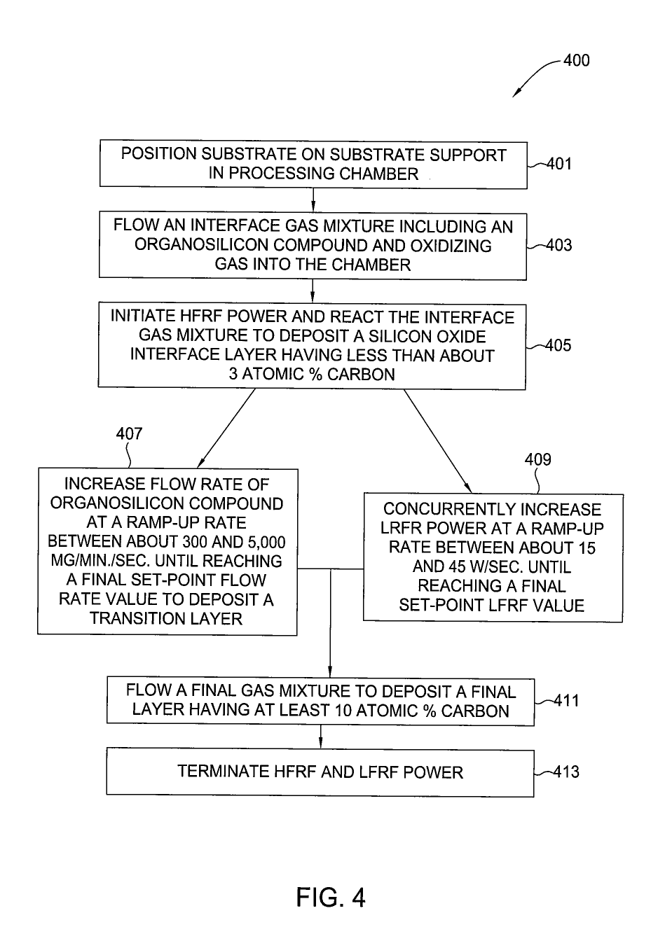

FIG. 4 is a process flow diagram illustrating a second embodiment of the invention that may be performed using a processing chamber such as the processing chamber shown in FIG. 3. In the embodiment shown in FIG. 4, an additional step of providing LFRF power during deposition is introduced in order to modulate the stress of the organosilicate dielectric layer. The process begins at 401, where a substrate is positioned on a substrate support in a processing chamber capable of performing PECVD. At 403, an interface gas mixture having a composition including a flow rate of one or more organosilicon compounds and a flow rate of one or more oxidizing gases is introduced into the chamber through a showerhead. At 405, HFRF power is applied to the showerhead in order to provide plasma processing conditions in the chamber. The interface gas mixture is reacted in the chamber in the presence of HFRF power applied to the showerhead to deposit an interface layer comprising a silicon oxide layer having less than 3 atomic percent carbon, and preferably less than 1 atomic percent carbon, that adheres strongly to the underlying substrate. At 407, the flow rate of the one or more organosilicon compounds is increased at a ramp-rate between about 300 mg/min./sec. and about 5,000 mg/min./sec. until reaching a predetermined final gas mixture. The flow rate of the one or more organosilicon compounds is increased in the presence of the HFRF, while concurrently increasing LFRF power, at 409, from an initial set-point value of about 0 W to a final set-point value employed during the deposition of the final layer at 411.

The changing process deposition conditions (e.g., gas mixture composition, RF frequency and power) are varied so as to ensure a variation in DC bias of the showerhead of less than 60 volts so as to avoid PID. The ramp-up rate of the LFRF power is preferably in a range of about 15 W/sec. to about 45 W/sec. Upon reaching the predetermined final gas mixture at 411, the final gas mixture is reacted in the chamber, in the presence of HFRF and LFRF power, to deposit a final layer comprising a carbon doped silicon oxide layer having at least 10 atomic percent carbon. During the reaction, the LFRF power may be at a final set-point value in a range of about 80 W to about 200 W, preferably less than about 160 W, and more preferably about 125 W. The HFRF and LFRF power is terminated at 413 after depositing the organosilicate dielectric layer to a desired thickness. The chamber pressure is maintained during the HFRF and LFRF power termination.

Optionally, measures 105 through 111 and 403 through 411 include varying the distance between the substrate and gas manifold, such as a showerhead or a gas distribution plate, in the processing chamber during the deposition process.

### Precursors and Processing Conditions for Deposition of Organosilicate Layers

In any of the embodiments described herein, an organosilicate dielectric layer is deposited from a process gas mixture comprising an organosilicon compound. The organosilicate layer may be used as a dielectric layer. The dielectric layer may be used at different levels within a device. For example, the dielectric layer may be used as a premetal dielectric layer, an intermetal dielectric layer, or a gate dielectric layer. The organosilicate layer is preferably a low-k dielectric layer, i.e., having a dielectric constant of less than about 3.0. In certain embodiments, such as high temperature applications, layers having dielectric constant up to about 3.6 are preferred. The organosilicon compound may serve as a silicon source, a carbon source, or both depending on the embodiment.

A wide variety of process gas mixtures may be used to deposit the organosilicate dielectric layer, and non-limiting examples of such gas mixtures are provided below. In some embodiments, the gas mixture includes one or more organosilicon compounds (e.g., a first and a second organosilicon compound, or just a single organosilicon compound), a carrier gas, and an oxidizing gas. These components are not to be interpreted as limiting, as many other gas mixtures including additional components such as hydrocarbons (e.g., aliphatic hydrocarbons) are contemplated.

The term “organosilicon compound” as used herein is intended to refer to silicon-containing compounds including carbon atoms in organic groups. The organosilicon compound may include one or more cyclic organosilicon compounds, one or more aliphatic organosilicon compounds, or a combination thereof. Some exemplary organosilicon compounds include tetramethylcyclotetrasiloxane (TMCTS), octamethylcyclotetrasiloxane (OMCTS), pentamethylcyclopentasiloxane, hexamethylcyclotrisiloxane, diethoxymethylsilane (DEMS), dimethyldisiloxane, tetrasilano-2,6-dioxy-4,8-dimethylene, tetramethyidisiloxane, hexamethyldisiloxane (HMDS), 1,3-bis(silanomethylene)disiloxane, bis(Imethyldisiloxanyl)methane, bis(I-methyldisiloxanyl)propane, hexamethoxydisiloxane (HMDOS), dimethyidimethoxysilane (DMDMOS), and dimethoxymethylvinylsilane (DMMVS), or derivatives thereof. The one or more organosilicon compounds may be introduced into the processing chamber at a flow rate in a range of about 100 sccm to about 5,000 sccm, preferably between about 500 sccm and about 3,000 sccm for low temperature applications, and between about 3,000 sccm and about 5,000 sccm for high temperature applications.

The gas mixture optionally includes one or more carrier gases. Typically, one or more carrier gases are introduced with the one or more organosilicon compounds into the processing chamber. Examples of carrier gases that may be used include helium, argon, carbon dioxide, and combinations thereof. The one or more carrier gases may be introduced into the processing chamber at a flow rate less than about 20,000 sccm, depending in part upon the size of the interior of the chamber. For low temperature applications, a preferred range for carrier gas flow is from about 500 sccm to about 1,500 sccm, and more preferably about 1,000 sccm. For high temperature applications, a preferred range for carrier gas flow is from about 2,000 sccm to about 5,000 sccm, such as about 3,000 sccm. In some processes, an inert gas such as helium or argon is put into the processing chamber to stabilize the pressure in the chamber before reactive process gases are introduced.

The gas mixture also includes one or more oxidizing gases. Suitable oxidizing gases include oxygen (O₂), ozone (O₃), nitrous oxide (N₂O), carbon monoxide (CO), carbon dioxide (CO₂), and combinations thereof. The flow of oxidizing gas may be in a range of about 100 sccm to about 3,000 sccm, depending in part upon the size of the interior of the chamber. Typically, the flow of oxidizing gas is in a range of about 100 sccm to about 1,000 sccm, such as about 200 sccm. Dissociation of oxygen or the oxygen containing compounds may occur in a microwave chamber prior to entering the deposition chamber and/or by RF power as applied to process gas within the chamber.

During deposition, a controlled plasma is typically formed in the chamber adjacent to the substrate by RF energy applied to the showerhead using an RF source 325 as depicted in FIG. 3. Alternatively, RF power can be provided to the substrate support. The plasma may be generated using high frequency RF (HFRF) power, as well as low frequency RF (LFRF) power (e.g., dual frequency RF), constant RF, pulsed RF, or any other known or yet to be discovered plasma generation technique. The RF source 325 can supply a single frequency HFRF between about 5 MHz and about 300 MHz. In addition, the RF source 325 may also supply a single frequency LFRF between about 300 Hz to about 1,000 kHz to supply a mixed frequency (HFRF and LFRF) to enhance the decomposition of reactive species of the process gas introduced into the process chamber. The RF power may be cycled or pulsed to reduce heating of the substrate and promote greater porosity in the deposited film. Suitable HFRF power may be a power in a range of about 10 W to about 5,000 W, preferably in a range of about 200 W to about 800 W. Suitable LFRF power may be a power in a range of about 0 W to about 5,000 W, preferably in a range of about 0 W to about 200 W.

During deposition, the substrate is maintained at a temperature between about −20° C. and about 500° C. For low temperature applications, the temperature is preferably maintained between about 100° C. and about 450° C. For high temperature applications, the temperature is preferably maintained between about 450° C. and about 600° C. The deposition pressure is typically between about 1 Torr and about 20 Torr, preferably between about 4 Torr and about 7 Torr. The deposition rate is typically between about 2,000 Å/min. and about 20,000 Å/min.

In some embodiments, an organosilicate dielectric layer may be deposited at temperatures exceeding about 450° C. The inventors have found that a dense low-k organosilicate layer may be formed by reacting an organosilicon precursor with an oxidizing gas as described herein at temperatures above about 450° C. The inventors have discovered that a deposition reaction performed at elevated temperatures eliminates volatile organic species from the film as it is deposited, resulting in lower inclusion of volatile organic or carbon-containing species in the film. An organosilicon precursor serving as a silicon source in such embodiments will generally have a ratio of silicon atoms to oxygen atoms no more than about 1.5. An organosilicon precursor serving as a carbon source will generally have a ratio of carbon atoms to silicon atoms of at least 1.6. Terminal methyl groups are still found in the films, but there is less carbon ring structure preserved in the film. Such films are more stable under subsequent high-temperature processing found in some embodiments. Manufacture of memory devices, for example, frequently requires subsequent processing at temperatures exceeding 600° C. Organosilicate dielectric layers deposited at low temperatures are generally not stable at higher temperatures, but high-temperature deposition yields a stable film. At temperatures above about 500° C., higher flowrates of the organosilicon precursor are required to yield desired film properties due to increased disruption of the precursor molecular structure during deposition. After depositing such a film, a memory device may be completed by forming openings in the film and filling the openings with a conductive material, such as a metal or metal alloy, such as copper, aluminum, or combinations thereof.

In one embodiment, a substrate is disposed in a process chamber and a first gas mixture is provided to a reaction zone in the process chamber. The first gas mixture may comprise an alkyl-substituted cyclotetrasiloxane compound, an oxidizing compound, and a carrier gas. The alkyl-substituted cyclotetrasiloxane compound may be any of those listed elsewhere herein, such as OMCTS. The temperature of the gas mixture in the reaction zone is maintained at or above 450° C., and dual-frequency RF power is applied to the reaction zone. The first gas mixture reacts to form a dense initiation layer having less than about 1 atomic percent carbon on the substrate. The quantity of the alkyl-substituted cyclotetrasiloxane compound is then increased to form a second gas mixture. The rate of increase of the alkyl-substituted cyclotetrasiloxane compound may be as described for other embodiments herein. After reacting the second gas mixture to form a dense bulk deposition layer on the substrate, the alkyl-substituted cyclotetrasiloxane compound is stopped to form a third gas mixture, and the third gas mixture reacts to form a hermetic oxide cap on the substrate. The deposited film generally has a carbon content less than about 5 atomic percent, and at least about 80 percent of the carbon atoms left in the deposited film are found in terminal methyl groups.

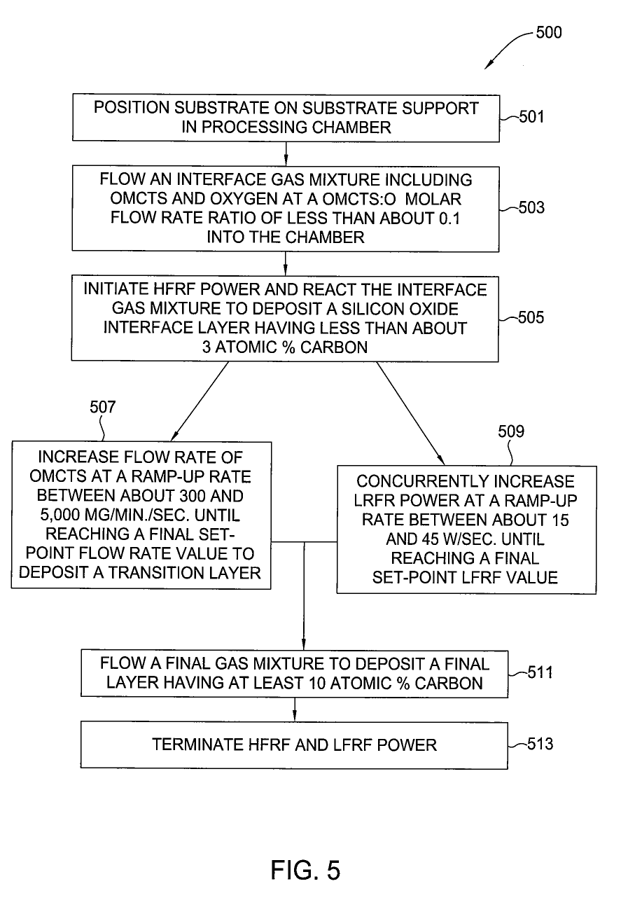

FIG. 5 is a process flow diagram illustrating a third embodiment of the invention that may be performed using a processing chamber such as the processing chamber shown in FIG. 3. In the embodiment shown in FIG. 5, an organosilicate dielectric layer is deposited according to the method described above with respect to FIG. 4 except OMCTS is used as the organosilicon compound, oxygen is used as the oxidizing gas, and helium is used as a carrier gas.

The process begins at 501, where a substrate is positioned on a substrate support in a processing chamber capable of performing PECVD. At 503, an interface gas mixture having a molar flow rate ratio of OMCTS:O₂ from about 0.05 to about 0.1 is introduced with helium into the chamber through a gas distribution manifold. At 505, HFRF power is initiated and applied to the gas distribution manifold in order to provide plasma processing conditions in the chamber. The interface gas mixture is reacted in the chamber in the presence of HFRF power to deposit an interface layer comprising a silicon oxide layer having less than 1 atomic percent carbon. The interface layer adheres strongly to the underlying substrate. At 507, the flow rate of OMCTS is increased at a ramp-rate between about 300 mg/min./sec. and about 5,000 mg/min./sec. until reaching a predetermined final set-point flow rate value of OMCTS. The flow rate of OMCTS is increased in the presence of the HFRF, while concurrently increasing a LFRF power, at 509, from an initial set-point value of about 0 W to a final set-point value employed during the deposition of the final layer at 511. The changing process deposition conditions (e.g., gas mixture composition, RF frequency and power) are varied so as to ensure a variation in DC bias of the gas distribution manifold of less than 60 volts so as to avoid PID. The ramp-up rate of the LFRF power is preferably in a range of about 15 W/sec. to about 45 W/sec. Upon reaching the predetermined final set-point flow rate value of OMCTS at 511, a final gas mixture having a composition including flowing the OMCTS at the final set-point flow rate value is reacted in the chamber, in the presence of HFRF and LFRF power, to deposit a final layer comprising a carbon doped silicon oxide layer having at least 10 atomic percent carbon. During the reaction, the LFRF power may be at a final set-point value in a range of about 80 W to about 200 W, preferably less than about 160 W, and more preferably about 125 W. The flow rate of carrier gas, such as helium, is preferably constant to reduce variation in DC bias, but can be varied if the variation in DC bias is less than 60 V. The HFRF and LFRF power is terminated at 513 after depositing the organosilicate dielectric layer to a desired thickness. The chamber pressure is maintained during the HFRF and LFRF power termination.

Adhesion of the low-k organosilicate dielectric layer to the underlying substrate or barrier layer depends on the adhesion strength of the interface layer to the underlying layer. In order to achieve an interface layer that exhibits high adhesion strength, the interface layer should be oxide-rich with a very low or nonexistent presence of C—H or —CH₃ terminating bonds. In other words, the interface layer should contain a ratio of less than 0.001 Si—CH₃ or C—H bonds in comparison to Si—O bonds.

Suppression of the —CH₃ terminating bonds depends on the composition of the gas mixture during the deposition of the interface layer. In particular, the ratio of the molar flow rate of organosilicon precursor to the molar flow rate of oxidizing gas may be varied to predetermine a sufficient ratio to deposit an interface layer having minimal —CH₃ terminating bonds and high adhesion energy.

In other embodiments, in addition to varying the composition of the gas mixture and the LFRF during deposition of the organosilicate dielectric layer, a controlled ramp-up of the HFRF power from 0 W to the initiation set-point value used to deposit the interface layer (e.g. about 500 W) is preferably performed prior to deposition of the interface layer, i.e., prior to step 103 in FIG. 1. The ramp rate may be less than about 300 W/sec., preferably less than about 200 W/sec., and more preferably less than about 100 W/sec. In a further embodiment, the RF power may also be ramped-down after beginning the deposition of the initiation layer in order to reduce the deposition rate of the initiation layer, i.e., thickness of the initiation layer.

In other embodiments, the flow rates of the inert gas and the oxidizing gas are preferably stabilized at the initiation set-point values (e.g., 1,000 sccm He and 700 sccm O₂), prior to deposition of the interface layer in order to avoid instability of process gas flow. In another embodiment, the one or more organosilicate precursor gases may be introduced into the chamber at a flow rate of about 100 mg/min. to about 200 mg/min. in order to prime the liquid delivery line as well as avoid instability of flow. During deposition, the organosilicate precursor gas flow may be increased at a ramp-up rate in a range of about 200 mg/min./sec. to about 5,000 mg/min./sec., and preferably in a range of about 300 mg/min./sec. to about 600 mg/min./sec., until reaching a final set-point value for subsequent deposition of the final layer of the organosilicate dielectric layer, in order to further avoid instability of flow and potential PID damage to the substrate.

Introducing the process gases gradually into the chamber and changing their values in a controlled manner with specific ramp-up or ramp-down rates and optionally varying the RF power, as described above, not only provides a dielectric layer with enhanced adhesion strength to the underlying substrate, but also improves the stability and uniformity of the plasma for minimizing potential PID damage to the substrate.

Following deposition of the film, the organosilicate dielectric layer may be post-treated, e.g., cured with heat, an electron beam (e-beam), or UV exposure. Post-treating the layer supplies energy to the film network to volatize and remove at least a portion of the organic groups, such as organic cyclic groups in the film network, leaving behind a more porous film network having a low dielectric constant. For high temperature applications, post treating is generally not needed because volatiles are mainly evacuated during film deposition.

### EXAMPLES

Organosilicate dielectric layers were deposited on a substrate in accordance with the embodiment described above with respect to FIG. 5. The films were deposited using a PECVD chamber (i.e., CVD chamber) on a PRODUCER system, available from Applied Materials, Inc. of Santa Clara, Calif. During deposition the chamber pressure was maintained at a pressure of about 4.5 Torr and the substrate was maintained at a temperature of about 350° C.

The substrate was positioned on a substrate support disposed within a process chamber. The process gas mixture having an initial gas composition of 1000 sccm helium and 700 sccm oxygen for the interface layer was introduced into the chamber and flow rates stabilized before initiation of the HFRF power. Subsequently, HFRF power of about 500 W was applied to the showerhead to form a plasma of the interface process gas mixture composition including a OMCTS flow rate of about 700 mg/min., and deposit a silicon oxide layer having a carbon content less than about 1 atomic percent. After initiation of the HFRF power for about 2 seconds, the flow rate of OMCTS was increased at a ramp-up rate of about 600 mg/min./sec. and concurrently LFRF power was increased at a ramp-up rate of about 30 W/sec. In addition, the flow of O₂ was decreased at a ramp-down rate of about 5,000 sccm/sec.

As the processing parameters are varied, a transition layer comprising increasing concentrations of carbon is deposited on the interface layer. Upon reaching the final set point values, HFRF power of about 500 W and LFRF power of about 125 W was applied to the gas distribution manifold to form a plasma of the final gas mixture composition including an OMCTS flow rate of about 2,700 mg/min. to begin depositing a carbon doped silicon oxide layer on the transition layer, the carbon doped silicon oxide layer having a carbon content in a range of about 20 atomic percent excluding hydrogen. The final gas mixture composition also includes 900 sccm helium and 160 sccm oxygen. The final HFRF power is 500 Wand the final LFRF power is 125 W. Upon reaching the desired thickness of the organosilicate dielectric layer, the RF power (HFRF and LFRF) is terminated to stop further deposition. After RF power termination, the chamber throttle valve is opened to allow the process gas mixture to be pumped out of the chamber.

Many variations of the above example may be practiced. For example, other organosilane precursors, oxidizing gases, and inert gases may be used. In addition, different flow rates and/or ramp rates may be employed. In one example TMCTS may be used as the organosilane precursor instead of OMCTS and the transition layer can be deposited while increasing the TMCTS flow at a rate of 150 sccm/min. In another example, the organosilane precursor may include a flow of trimethylsilane combined with a flow of OMCTS. In another example, the interface layer may be deposited using both HFRF and LFRF (i.e., with a non-zero LFRF value). The time for depositing the dielectric layer may be varied from 0.5 to 5 seconds.

Table 1 shows reactions conditions for three high-temperature low-k organosilicate films, and properties thereof. Each of the films were annealed at 600° C. for 4 hours after deposition.

TABLE 1

| | | | |
|---|---|---|---|
| Temperature, ° C. | 350 | 450 | 550 |
| Pressure, Torr | 5 | 5 | 5 |
| Spacing, mils | 400 | 400 | 400 |
| HF Power, W | 300 | 300 | 300 |
| LF Power, W | 60 | 60 | 60 |
| OMCTS, mgm | 3600 | 3600 | 4400 |
| He, sccm | 3000 | 3000 | 3000 |
| O₂, sccm | 200 | 200 | 200 |
| k | 3.3 | 3.45 | 3.58 |
| Shrinkage, percent | 2.18 | 1.46 | 0.86 |
| Stress, MPa | 36 | 89 | 72 |

From this data, it can readily be seen that low-k organosilicate films can be deposited at high temperatures. The films thus deposited are denser than those deposited at lower temperatures, and more heat stable.

While the foregoing is directed to embodiments of the invention, other and further embodiments of the invention may be devised without departing from the basic scope thereof.

What is claimed is:

1. A method of forming a memory device, comprising:
depositing a dense low-k dielectric film comprising silicon, oxygen, and carbon, and having one or more terminal methyl groups;
removing volatile carbon-containing species from the film while depositing the dense low-k dielectric film;
forming openings in the dense low-k dielectric film; and
filling the openings in the dense low-k dielectric film with a conductive material, wherein depositing the dense low-k dielectric film comprises reacting a gas mixture comprising a silicon precursor, a carbon precursor, and an oxygen precursor in the presence of RF power at a temperature at or above about 450° C., and removing volatile carbon-containing species from the film comprises maintaining the substrate at a temperature at or above about 450° C.

2. The method of claim 1, wherein the silicon source and the carbon source are the same compound, and the compound has an atomic ratio of silicon to oxygen of no more than about 1.5.

3. The method of claim 1, wherein the silicon precursor comprises silicon-oxygen bonds and the carbon precursor comprises silicon-carbon bonds.

4. The method of claim 10, wherein the silicon source and the carbon source are the same compound.

5. The method of claim 1, wherein the dense low-k dielectric film has a dielectric constant less than about 3.6.

6. The method of claim 5, wherein the RF power comprises a high-frequency power and a low-frequency power, wherein a power level of the high-frequency power and a power level of the low-frequency power are in a ratio of at least about 4:1.

7. A method of forming a memory device on a substrate, comprising:
reacting a gas mixture comprising a silicon precursor, a carbon precursor, and an oxygen precursor at a temperature at or above about 450° C. in the presence of RF power;
depositing a low-k film having terminal methyl groups incorporated therein;
forming openings in the low-k film; and
filling the openings with a conductive material.

8. The method of claim 7, wherein the silicon precursor and the carbon precursor are the same compound.

9. The method of claim 7, wherein the silicon precursor and the carbon precursor are the same compound, and the compound has an atomic ratio of silicon to oxygen no more than about 1.5.

10. The method of claim 9, wherein the low-k film is a dense film.

11. The method of claim 9, wherein the compound has an atomic ratio of carbon to silicon at least about 1.6.

12. The method of claim 7, wherein the silicon precursor comprises silicon-oxygen bonds, and the carbon precursor comprises silicon-carbon bonds.

13. The method of claim 10, wherein the conductive material is a material selected from the group consisting of copper, aluminum, and combinations thereof.

14. The method of claim 7, wherein the low-k film comprises less than 5 atomic percent carbon.

15. The method of claim 14, wherein at least about 80 percent of the carbon atoms are terminal carbon atoms.

16. The method of claim 7, further comprising forming a hermetic oxide cap on the low-k film.

17. The method of claim 10, further comprising exposing the dense film to an oxidizing gas.

18. A method of forming a device on a substrate, comprising:
disposing the substrate in a process chamber;
providing a first gas mixture comprising an alkyl-substituted cyclotetrasiloxane compound, an oxidizing compound, and a carrier gas, to a reaction zone in the process chamber;
maintaining a temperature of the gas mixture in the reaction zone at a temperature at or above 450° C.;
applying dual-frequency RF power to the reaction zone;
reacting the first gas mixture to form a dense initiation layer on the substrate;
increasing the quantity of the alkyl-substituted cyclotetrasiloxane compound to form a second gas mixture;
reacting the second gas mixture to form a dense bulk deposition layer on the substrate;
stopping the alkyl-substituted cyclotetrasiloxane compound to form a third gas mixture; and
reacting the third gas mixture to form a hermetic oxide cap on the substrate.

19. The method of claim 18, wherein reacting the second gas mixture comprises eliminating volatile species from the dense bulk deposition layer.

20. The method of claim 18, wherein the temperature is at least 500° C.
